(19) United States
(12) Patent Application Publication
(10) Pub. No.: US 2008/0265337 A1
(43) Pub. Date: Oct. 30, 2008

(54) SEMICONDUCTOR DEVICE FABRICATION METHOD AND SEMICONDUCTOR DEVICE

(75) Inventor: Hiroshi MINAKATA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/169,719

(22) Filed: Jul. 9, 2008

Related U.S. Application Data
(63) Continuation of application No. PCT/JP2006/301117, filed on Jan. 25, 2006.

(51) Int. Cl. H01L 27/088; H01L 21/311

(52) U.S. Cl. 257/392; 438/703; 257/E27.06; 257/E21.249

(57) ABSTRACT

A semiconductor device fabrication method for forming a gate insulating film of a low leakage transistor and a gate insulating film of a high performance transistor. A first SiON film is formed over a Si substrate through first film formation. The first SiON film is left where the low leakage transistor is to be formed, and is removed where the high performance transistor is to be formed. Through second film formation, a second SiON film is formed where the first SiON film is removed, and a third SiON film including the first SiON film is formed where the first SiON film is left. The formed first SiON film has thickness and nitrogen concentration so that the third SiON film has thickness and nitrogen concentration to be the gate insulting film of the low leakage transistor.

This application is a continuing application, filed under 35 U.S.C. §111(a), of International Application PCT/JP2006/301117, filed on Jan. 25, 2006.

### BACKGROUND OF THE INVENTION

(1) Field of the Invention

This invention relates to a method for fabricating a semiconductor device and a semiconductor device and, more particularly, to a method for fabricating a semiconductor device including a metal insulator semiconductor (MIS) transistor and a semiconductor device including such a transistor.

(2) Description of the Related Art

With semiconductor devices having an I/O section and a core section, usually a drive transistor included in the I/O section functions as an interface with the outside of the device and an operation circuit or a memory circuit included in the core section processes or stores information. Metal oxide semiconductor (MOS) field-effect transistors are widely used in I/O sections, dynamic random access memories (DRAMs), static random access memories (SRAMs), or the like are widely used in memory circuits of core sections, and CMOS logic circuits or the like are widely used in operation circuits of core sections.

A transistor for I/O differs from a transistor for operation in power supply voltage or target performance. Accordingly, if transistors for I/O and transistors for operation are formed over one semiconductor substrate, the method of, for example, forming gate insulating films of different thicknesses according to uses for the transistors is used. However, usually the difference in thickness between the gate insulating films is about several nanometers. In addition, the following method may be used for obtaining a desired performance difference. Channel regions or source/drain regions are doped with ions under different conditions according to the difference in thickness between the gate insulating films or the kind of the gate insulating films. By doing so, impurity concentration is controlled.

To date the following method, for example, has been proposed as a method for forming gate insulating films of different thicknesses. A silicon oxide (SiO₂) film of predetermined thickness is formed in a first region over a silicon (Si) substrate, a silicon oxide nitride (SiON) film with a predetermined concentration of nitrogen (N) which is thinner than the SiO₂ film is formed in a second region over the Si substrate, and a SiON film which is thinner than the SiON film formed in the second region and which is lower in nitrogen concentration than the SiON film formed in the second region is formed in a third region over the Si substrate. Radical nitriding treatment is performed on the whole of these films (see Japanese Patent Laid-Open Publication No. 2002-368122). With this method, gate insulating films of different thicknesses are formed in the three regions. In addition, an attempt to optimize the physical thickness and permittivity of a gate insulating film formed in each region is made by introducing a predetermined amount of nitrogen into each gate insulating film.

In addition to the necessity of forming transistors of different types in an I/O section and a core section, the necessity of forming transistors of different types in a core section has recently increased. The case where a low leakage transistor for which importance is attached to suppression of a leakage current and a high performance transistor for which importance is attached to operating speed are formed in a core section can be given as a concrete example. In this case, a gate insulating film of the low leakage transistor is formed thick and a gate insulating film of the high performance transistor is formed thin. In addition, at present the difference in thickness between the gate insulating films of the low leakage transistor and the high performance transistor must be set to a very small value, that is to say, to a value smaller than 1 nm.

If transistors having gate insulating films between which there is a comparatively great difference in thickness are formed in an I/O section and a core section, the following method, for example, has traditionally been adopted. A gate insulating film of a transistor included in an I/O section is formed thick of SiO₂ or SiON mainly with breakdown voltage taken into consideration. On the other hand, a gate insulating film of a transistor included in a core section is formed thin of SiON mainly with film thickness and permittivity taken into consideration. To be concrete, the following steps, for example, are performed. A SiO₂ film is formed first over a Si substrate. The SiO₂ film is removed only in the core section by the use of hydrofluoric acid (HF) or the like. A SiON film in which nitrogen concentration is suitable for the transistor included in the core section is formed only over the exposed Si substrate in the core section or over the exposed Si substrate in the core section and the SiO₂ film left in the I/O section.

However, if this conventional method by which the gate insulating films of the transistors included in the I/O section and the core section can be formed is applied without any change to the formation of gate insulating films of a low leakage transistor and a high performance transistor included in a core section, then the following problems arise.

As stated above, when the gate insulating films of the low leakage transistor and the high performance transistor included in the core section are formed, the difference in thickness between these gate insulating films must be set to a very small value, that is to say, to a value smaller than 1 nm. In addition, a nitrogen concentration profile in a gate insulating film of each transistor has a great influence on its performance.

If gate insulating films which are formed in the core section and between which the difference in thickness is very small differ significantly in nitrogen concentration profile, then a transistor design or a process condition must be changed so that the performance of transistors finally obtained will be suitable for the core section. For example, conditions under which a channel region or source/drain regions are doped with ions must be changed. Therefore, if gate insulating films between which the difference in thickness is very small and which are equal in nitrogen concentration profile can be formed, then there is no need to change the conventional manufacturing conditions except in the step of forming the gate insulating films.

If the above conventional method is applied without any change to the formation of the gate insulating films of the low leakage transistor and the high performance transistor included in the core section, it is technically possible to form the gate insulating films of the low leakage transistor and the high performance transistor between which the difference in thickness is a very small desired value by properly controlling conditions under which the gate insulating films are formed. However, if a SiON film in which nitrogen concentration is suitable for the high performance transistor is formed over a SiO₂ film in accordance with the above steps, a thick gate insulating film of the low leakage transistor differs significantly from the gate insulating film of the high performance transistor which is the SiON film formed directly on a Si substrate in nitrogen concentration profile.

On the other hand, the following method may be used for forming different gate insulating films. SiO₂ films between which the difference in thickness is very small are formed first over a Si substrate. Nitriding treatment is then performed on the whole of these SiO₂ films. By doing so, SiON films between which the difference in thickness is a very small predetermined value are formed. However, even if this method is used and the difference in thickness between the SiON films obtained after nitriding treatment is a very small value, that is to say, a value smaller than 1 nm, these SiON films differ significantly in nitrogen concentration profile.

FIG. 10 is a view showing an example of a nitrogen concentration profile.

In the case of FIG. 10, SiO₂ films with thicknesses of about 0.8 and 0.9 nm between which the difference in thickness is very small are formed first over a Si substrate. Nitriding treatment is then performed on the whole of the SiO₂ films. By doing so, SiON films are formed over the Si substrate. FIG. 10 shows nitrogen concentration profiles of these SiON films. In this example, oxynitridation is performed as nitriding treatment by the use of nitric oxide (NO) gas. In FIG. 10, a horizontal axis indicates the depth (nm) in the direction of the Si substrate of each SiON film after nitriding treatment and a vertical axis indicates nitrogen concentration (%) in each SiON film.

The thickness of the SiON film formed in a region where the SiO₂ film with a thickness of about 0.8 nm is formed was about 1.150 nm. The thickness of the SiON film formed in a region where the SiO₂ film with a thickness of about 0.9 nm is formed was about 1.190 nm. The difference in thickness between these SiON films is very small. As can be seen from FIG. 10, nitrogen concentration (indicated by “1.190 nm” in FIG. 10) in the SiON film obtained by performing nitriding treatment on the SiO₂ film formed thicker is lower than nitrogen concentration (indicated by “1.150 nm” in FIG. 10) in the SiON film obtained by performing nitriding treatment on the SiO₂ film formed thinner. Moreover, a difference of about 0.6% exists between nitrogen concentration at an interface between the Si substrate and the SiON film obtained by performing nitriding treatment on the SiO₂ film formed thicker and nitrogen concentration at an interface between the Si substrate and the SiON film obtained by performing nitriding treatment on the SiO₂ film formed thinner.

That is to say, even if the difference in thickness between SiO₂ films is very small before nitriding treatment, nitrogen concentration profiles of SiON films obtained after nitriding treatment differ. If this method is applied to the formation of gate insulating films of a low leakage transistor and a high performance transistor included in a core section, an unnecessary performance difference arises between these transistors or conditions under which another step is performed must be changed after the formation of the gate insulating films.

In each of the above conventional methods nitriding treatment may be performed only in a region where nitrogen concentration is low. In this case, however, the following method, for example, must be adopted. SiON films which differ in thickness and nitrogen concentration are formed first, a SiON film with a higher concentration of nitrogen is then protected, and only a SiON film with a lower concentration of nitrogen is then doped with nitrogen. As a result, problems arise. For example, the process for fabricating a semiconductor device becomes complex.

### SUMMARY OF THE INVENTION

The present invention was made under the background circumstances described above. An object of the present invention is to provide a semiconductor device fabrication method by which a high performance semiconductor device with high reliability including transistors having gate insulating films between which the difference in thickness is a predetermined value and which show predetermined nitrogen concentration profiles can efficiently be fabricated.

Another object of the present invention is to provide a high performance semiconductor device with high reliability including transistors having gate insulating films between which the difference in thickness is a predetermined value and which show predetermined nitrogen concentration profiles.

In order to achieve the above first object, a method for fabricating a semiconductor device having transistors of plural types in which gate insulating films of different thicknesses are used is provided. This method comprises the steps of forming a first silicon oxide nitride film over a silicon substrate by performing first film formation on the silicon substrate, leaving the first silicon oxide nitride film formed over the silicon substrate in a region in which one transistor is to be formed and removing the first silicon oxide nitride film formed over the silicon substrate in a region in which an other transistor is to be formed, and performing second film formation in the region in which the one transistor is to be formed and in which the first silicon oxide nitride film is left and the region in which the other transistor is to be formed and in which the first silicon oxide nitride film is removed for forming a second silicon oxide nitride film in the region in which the other transistor is to be formed and in which the first silicon oxide nitride film is removed and for forming a third silicon oxide nitride film including the first silicon oxide nitride film in the region in which the one transistor is to be formed and in which the first silicon oxide nitride film is left.

In order to achieve the above second object, a semiconductor device having transistors of plural types in which gate insulating films of different thicknesses are used is provided. In this semiconductor device, a difference in thickness between a gate insulating film of one transistor and a gate insulating film of an other transistor is greater than or equal to 0.03 nm and smaller than or equal to 0.15 nm and the gate insulating film of the one transistor and the gate insulating film of the other transistor are equal in nitrogen concentration profile.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a view showing a flow chart of fabricating a semiconductor device.

FIG. 2 is a fragmentary schematic sectional view showing the step of forming an isolation insulating film.

FIG. 3 is a fragmentary schematic sectional view showing a first film formation step.

FIG. 4 is a fragmentary schematic sectional view showing the step of forming photoresist.

FIG. 5 is a fragmentary schematic sectional view showing an etching step.

FIG. 6 is a fragmentary schematic sectional view showing a second film formation step.

FIG. 7 is a fragmentary schematic sectional view showing the step of forming a polycrystalline silicon film.

FIG. 8 is a fragmentary schematic sectional view showing the step of fabricating gates.

FIG. 9 is a fragmentary schematic sectional view showing the step of forming side walls and impurity diffusion regions.

FIG. 10 is a view showing an example of a nitrogen concentration profile.

### DESCRIPTION OF THE PREFERRED EMBODIMENTS

Embodiments of the present invention will now be described in detail with reference to the drawings.

An overview of a method for fabricating a semiconductor device will be given first.

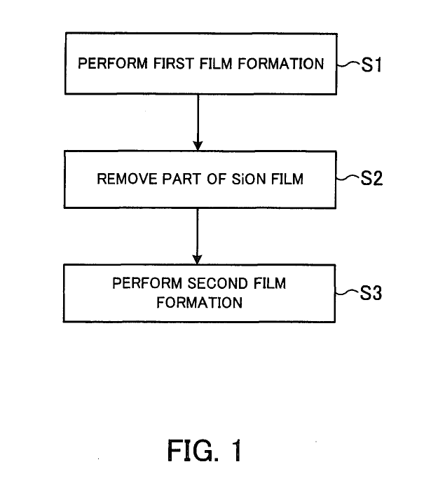

FIG. 1 is a view showing a flow chart of fabricating a semiconductor device.

A flow chart of fabricating a semiconductor device including transistors of two types, that is to say, a first transistor and a second transistor (referred to as a thick-film transistor and a thin-film transistor respectively) having gate insulating films which differ in thickness and which contain nitrogen will be described.

Film formation is performed first on a Si substrate (first film formation). That is to say, a SiON film (first SiON film) of predetermined thickness with a predetermined concentration of nitrogen is formed over the Si substrate (step S1). The thickness of and the concentration of nitrogen in the first SiON film formed in the first film formation should be set so that a SiON film obtained at the time of performing film formation (second film formation) described later on the first SiON film will attain thickness and nitrogen concentration necessary to a gate insulating film of the thick-film transistor.

Various methods can be used for forming the first SiON film. For example, the method of oxynitriding the surface of the Si substrate by the use of gas, such as NO gas, which contains nitrogen, the method of forming a SiO₂ film over the Si substrate and plasma-nitriding the SiO₂ film, the method of forming a SiO₂ film over the Si substrate and oxynitriding the SiO₂ film by the use of NO gas or the like, or the method of forming a SiO₂ film and a silicon nitride (SiN) film in order over the Si substrate can be used.

After the first SiON film of predetermined thickness with a predetermined concentration of nitrogen is formed in the first film formation, the first SiON film that is formed over the Si substrate and that is in a region (thin-film transistor formation region) in which the thin-film transistor is to be formed is removed (step S2) to expose the Si substrate. At this time the following method, for example, is used. A region (thick-film transistor formation region) in which the thick-film transistor is to be formed is protected by, for example, photoresist and the first SiON film in the thin-film transistor formation region is wet-etched by HF or the like.

At this time the first SiON film is exposed in the thick-film transistor formation region and the Si substrate is exposed in the thin-film transistor formation region. After that, a SiON film (second SiON film) of predetermined thickness with a predetermined concentration of nitrogen is formed over the exposed Si substrate as second film formation (step S3). In this second film formation the second SiON film the thickness of which and the concentration of nitrogen in which are necessary to a gate insulating film of the thin-film transistor is formed in the thin-film transistor formation region over the Si substrate. Preferably, an oxynitridation method in which NO gas or the like is used should be adopted for forming the second SiON film. However, another method may be used. This is the same with the formation of the first SiON film.

The second film formation is also performed in the thick-film transistor formation region. As a result, a SiON film (third SiON film) which is thicker than the first SiON film before the second film formation and in which nitrogen concentration is higher than nitrogen concentration in the first SiON film before the second film formation is formed in the thick-film transistor formation region. In the above step S1 conditions under which the first film formation is performed for forming the first SiON film are set properly so that the third SiON film obtained after the second film formation will attain thickness and nitrogen concentration necessary to the gate insulating film of the thick-film transistor. When the conditions are set, the difference in oxynitridation rate among the exposed Si substrate, the first SiON film, and the Si substrate over which the first SiON film is formed should be taken into consideration in order to obtain desired thickness and nitrogen concentration.

The third and second SiON films are formed in the thick-film transistor formation region and the thin-film transistor formation region, respectively, in this way. After that, gate electrodes, side walls, source/drain regions, interlayer dielectrics, plugs, pads, and the like are formed in accordance with an ordinary method to complete a semiconductor device.

As has been described, to form the thick-film transistor and the thin-film transistor, that is to say, the transistors of the two types, the first SiON film of predetermined thickness with a predetermined concentration of nitrogen is formed first in advance only in the thick-film transistor formation region by the first film formation. The second film formation is then performed both in the thin-film transistor formation region where the Si substrate is exposed and in the thick-film transistor formation region where the first SiON film is formed. By doing so, the second SiON film the thickness of which and the concentration of nitrogen in which are necessary to the gate insulating film of the thin-film transistor is formed in the thin-film transistor formation region. At the same time the third SiON film the thickness of which and the concentration of nitrogen in which are necessary to the gate insulating film of the thick-film transistor is formed in the thick-film transistor formation region. As a result, the gate insulating films of the thick-film transistor and the thin-film transistor, that is to say, of the transistors of the two types the thickness of which and the concentration of nitrogen in which are most suitable can be formed.

For example, nitrogen concentration in the first SiON film formed by the first film formation is controlled so that the third SiON film in the thick-film transistor formation region will become equal in nitrogen concentration to the second SiON film in the thin-film transistor formation region after the second film formation. By doing so, the thick-film transistor and the thin-film transistor, that is to say, the transistors of the two types having gate insulating films which differ in thickness and which are equal in nitrogen concentration profile can be formed.

To form gate insulating films which differ in thickness, the method of using a SiO₂ film has traditionally been used. That is to say, a thick film is formed of a SiO₂ film and a SiON film and a thin film is formed of a SiON film. Alternatively, a thick SiO₂ film and a thin SiO₂ film are formed and these are nitrided. If this method is adopted, it is possible to secure a predetermined difference in thickness between the thick film and the thin film. However, it is very difficult to make the thick film and the thin film equal in nitrogen concentration profile. With the method shown in FIG. 1, SiON films are used. In this case, the thick-film transistor and the thin-film transistor having gate insulating films between which a minute difference in thickness exists and which are equal in nitrogen concentration profile can be formed by properly setting conditions under which the first and second film formation is performed for forming the SiON films.

In the above example, the transistors of the two types having gate insulating films which contain nitrogen and which differ in thickness are formed. However, it is a matter of course that the above method is also applicable to the formation of transistors of three or more types having gate insulating films which differ in thickness.

The above method will now be described concretely with the case where transistors of two types having gate insulating films which contain nitrogen and which differ in thickness are formed in a core section of a semiconductor device having an I/O section and the core section as an example. In this case, a low leakage transistor (corresponding to the above thick-film transistor) and a high performance transistor (corresponding to the above thin-film transistor) are formed as transistors of two types.

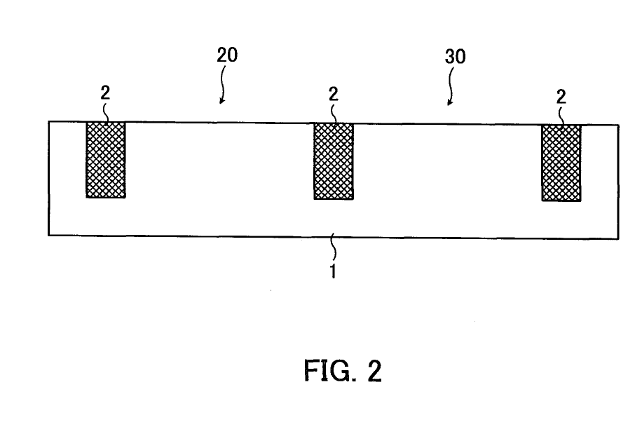

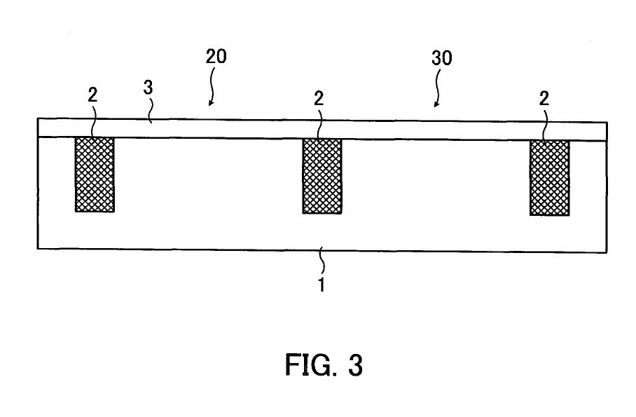

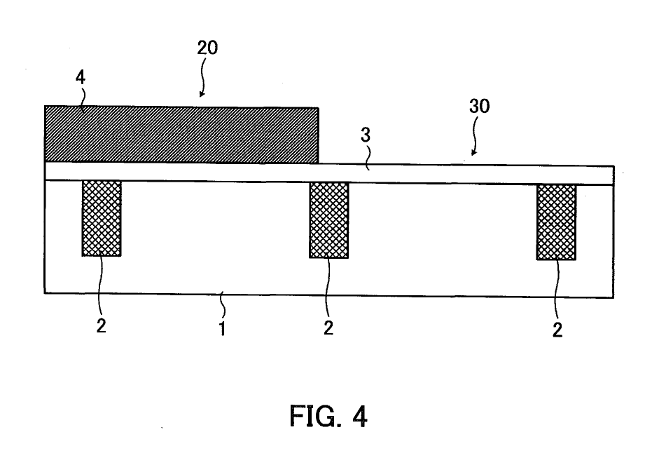

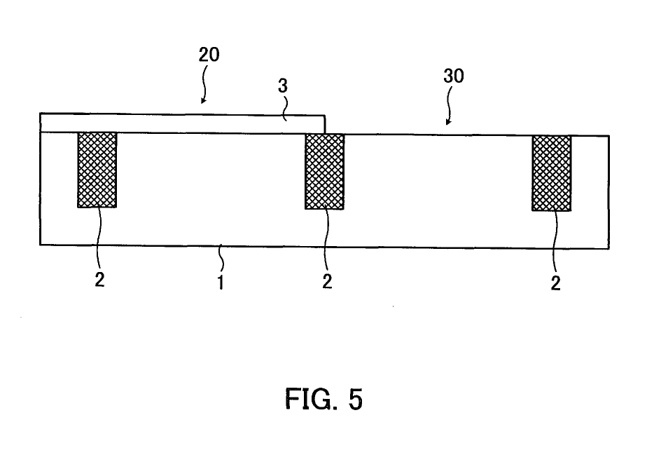

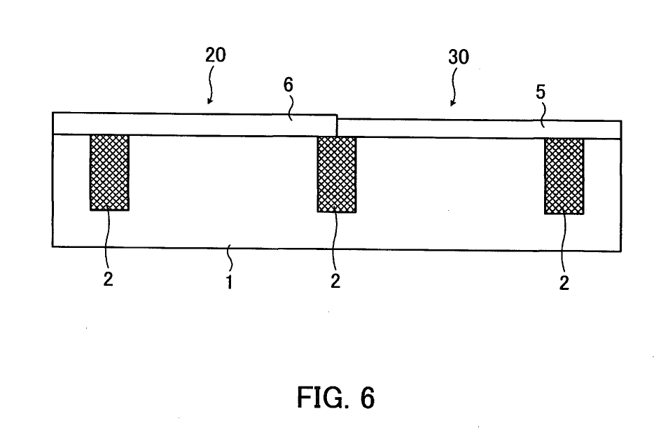

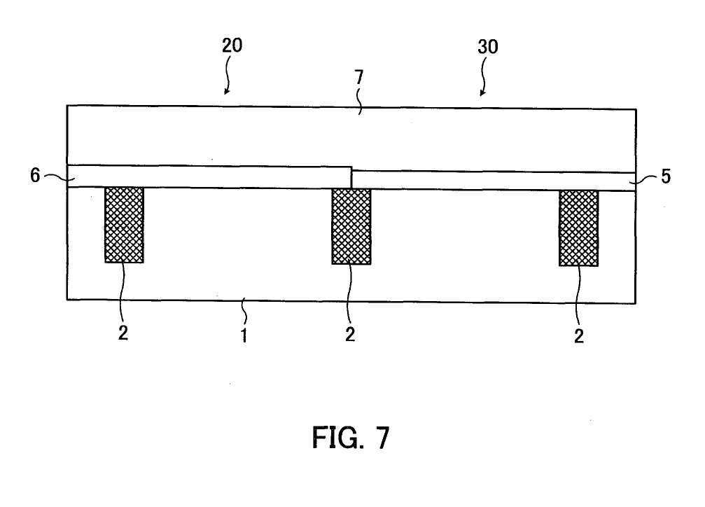

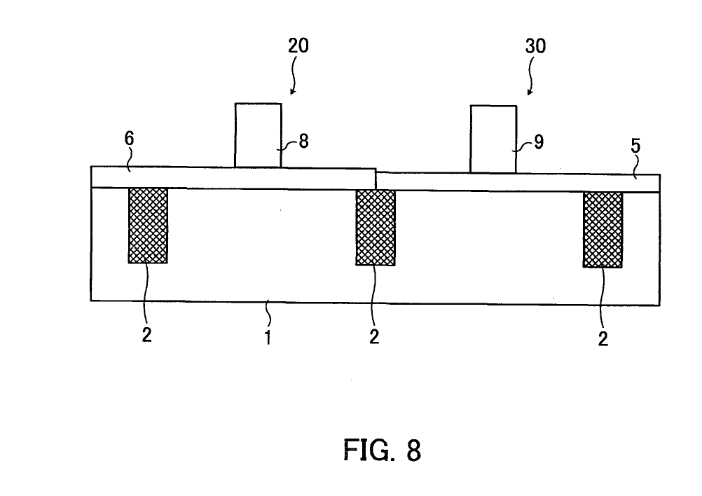

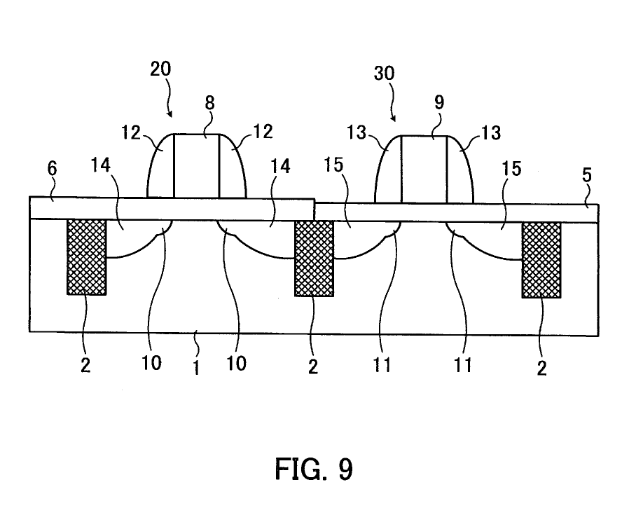

FIGS. 2 through 9 are views for describing a method for fabricating a semiconductor device. FIG. 2 is a fragmentary schematic sectional view showing the step of forming an isolation insulating film. FIG. 3 is a fragmentary schematic sectional view showing a first film formation step. FIG. 4 is a fragmentary schematic sectional view showing the step of forming photoresist. FIG. 5 is a fragmentary schematic sectional view showing an etching step. FIG. 6 is a fragmentary schematic sectional view showing a second film formation step. FIG. 7 is a fragmentary schematic sectional view showing the step of forming a polycrystalline silicon film. FIG. 8 is a fragmentary schematic sectional view showing the step of fabricating gates. FIG. 9 is a fragmentary schematic sectional view showing the step of forming side walls and impurity diffusion regions.

As shown in FIG. 2, an isolation insulating film 2 is formed first in predetermined regions of a Si substrate 1 by a shallow trench isolation (STI) method to define a region (low leakage transistor formation region) 20 where a low leakage transistor is to be formed and a region (high performance transistor formation region) 30 where a high performance transistor is to be formed.

After an RCA cleaning of the Si substrate 1 is performed, channel regions are doped with ions at need for controlling thresholds. As shown in FIG. 3, a first SiON film 3 is formed by the first film formation. The first SiON film 3 is formed in the first film formation so that a SiON film formed later by the second film formation will attain thickness and nitrogen concentration necessary to a gate insulating film of the low leakage transistor. For example, the first SiON film 3 with a thickness of about 1.0 nm is formed. As stated above, the method of oxynitriding the surface of the Si substrate 1 by the use of NO gas or the like, the method of forming a SiO₂ film over the Si substrate 1 and plasma-nitriding the SiO₂ film, the method of forming a SiO₂ film over the Si substrate 1 and oxynitriding the SiO₂ film by the use of NO gas or the like, or the method of forming a SiO₂ film and a SiN film in order over the Si substrate 1 is used for forming the first SiON film 3.

As shown in FIG. 4, only the low leakage transistor formation region 20 is then covered with photoresist 4. Wet etching is performed by the use of HF or the like with the photoresist 4 as a mask. By doing so, as shown in FIG. 5, the first SiON film 3 in the high performance transistor formation region 30 is removed and the Si substrate 1 gets exposed. The photoresist 4 is then exfoliated and removed.

As a result, the first SiON film 3 is left in the low leakage transistor formation region 20 and the Si substrate 1 is exposed in the high performance transistor formation region 30. The second film formation is performed in this state. As shown in FIG. 6, a second SiON film 5 the thickness of which and the concentration of nitrogen in which are necessary to a gate insulating film of the high performance transistor is formed in the high performance transistor formation region 30 where the Si substrate 1 is exposed by the second film formation. For example, the method of oxynitriding the Si substrate 1 by the use of NO gas or the like can be used for forming the second SiON film 5.

The second SiON film 5 is formed in this way in the high performance transistor formation region 30 by the second film formation. At the same time the second film formation is performed in the low leakage transistor formation region 20. As a result, a third SiON film 6 which is thicker than the first SiON film 3 and in which nitrogen concentration is higher than nitrogen concentration in the first SiON film 3 is formed in the low leakage transistor formation region 20.

As stated above, conditions under which the second film formation is performed should be set so that the second SiON film 5 formed in the high performance transistor formation region 30 will attain thickness and nitrogen concentration necessary to the gate insulating film of the high performance transistor. Conditions under which the first film formation is performed for forming the first SiON film 3 should be set properly so that the third SiON film 6 which is formed simultaneously with the second SiON film 5 will attain thickness and nitrogen concentration necessary to the gate insulating film of the low leakage transistor after the second film formation. When these conditions are set, the difference in oxynitridation rate among the exposed Si substrate 1, the first SiON film 3, and the Si substrate 1 over which the first SiON film 3 is formed should be taken into consideration in order to obtain desired thickness and nitrogen concentration.

By properly setting the conditions under which the first film formation and the second film formation are performed in this way, gate insulating films which differ in thickness and between which a predetermined difference in thickness exists can be formed in the low leakage transistor formation region 20 and the high performance transistor formation region 30. For example, a thin gate insulating film with a thickness of 2 nm or less and a thinner gate insulating film between which a predetermined difference in thickness exists can ultimately be formed in the low leakage transistor formation region 20 and the high performance transistor formation region 30 respectively.

If, as is described in the above example, a low leakage transistor and a high performance transistor, that is to say, transistors of two types are formed in a core section, the difference in thickness between gate insulating films should be below 1 nm, and preferably in the range of 0.03 to 0.15 nm. In principle, gate insulating films between which any difference in thickness exists can be formed. However, if the low leakage transistor and the high performance transistor are formed in the core section, it is effective to set the difference in thickness between the gate insulating films to 0.15 nm or less. If the difference in thickness between the gate insulating films of the low leakage transistor and the high performance transistor is below 0.03 nm, the difference in performance between the low leakage transistor and the high performance transistor becomes small. Accordingly, it is desirable that the difference in thickness between the gate insulating films of the low leakage transistor and the high performance transistor should be set to 0.03 nm or more.

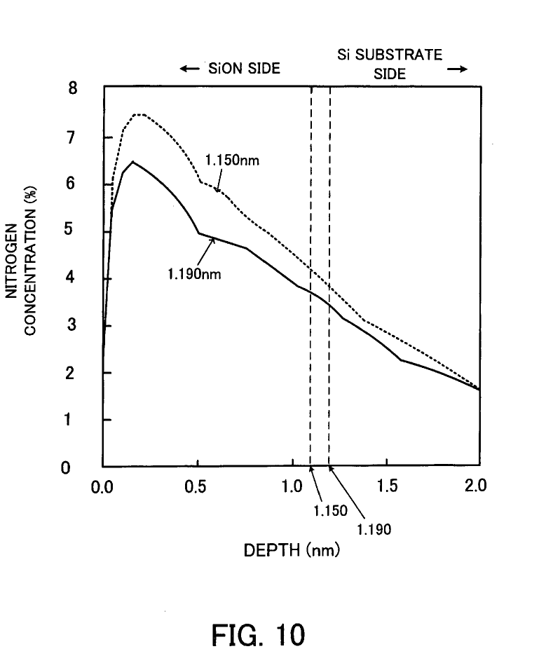

In addition, by properly setting the conditions under which the first film formation and the second film formation are performed, gate insulating films between which a predetermined difference in thickness exists and which are equal in nitrogen concentration profile can be formed in the low leakage transistor formation region 20 and the high performance transistor formation region 30. With the conventional method in which gate insulating films between which a predetermined difference in thickness exists are formed by using not a SiON film (first SiON film 3) but a SiO₂ film, it was difficult to make the gate insulating films equal in nitrogen concentration profile (see FIG. 10). With the above method according to the present invention, however, a SiON film is used and the conditions under which the first film formation and the second film formation are performed are set properly. By doing so, it is possible to make gate insulating films equal in nitrogen concentration profile. In particular, the difference in nitrogen concentration between an interface between one gate insulating film and the Si substrate 1 and an interface between the other gate insulating film and the Si substrate 1 can be narrowed down to 0.5% or less.

As shown in FIG. 7, a chemical vapor deposition (CVD) method is used for forming a polycrystalline silicon film 7 of predetermined thickness over an entire surface after the gate insulating films are formed in this way. The polycrystalline silicon film 7 is then treated into a predetermined shape by etching. As shown in FIG. 8, gate electrodes 8 and 9 are formed in the low leakage transistor formation region 20 and the high performance transistor formation region 30 respectively.

As shown in FIG. 9, LDD (lightly doped drain) regions 10 and 11 are formed in the Si substrate 1 by performing ion implantation. After that, side walls 12 and 13 are formed on both sides of the gate electrodes 8 and 9 respectively. Implantation of predetermined impurity ions and activation are performed to form source/drain regions 14 and 15. Interlayer dielectrics, plugs, pads, and the like (not shown) are then formed in accordance with an ordinary fabrication process to complete a semiconductor device.

In the above example, descriptions of the method for forming the transistors of the two types in the core section are given. In addition to the transistors of the core section each having the above structure, however, transistors are formed in the I/O section of the semiconductor device. With each transistor formed in the I/O section, importance is attached mainly to the thickness of a gate insulating film. Accordingly, the following method, for example, is adopted. A SiO₂ or SiON film of predetermined thickness is formed in a region where I/O transistors are to be formed before the first SiON film 3 is formed. The first SiON film 3 is then formed. After that, the same steps that are performed for forming the above transistors of the core section should be followed.

As has been described in the foregoing, with the above semiconductor device fabrication method according to the present invention a low leakage transistor and a high performance transistor having gate insulating films between which a predetermined difference in thickness exists and which are equal in nitrogen concentration profile can be formed in a core section. This method can be realized only by changing the gate insulating film formation step of the conventional semiconductor device fabrication method. Therefore, the different transistors can be formed in the core section without changing conditions under which another step is performed. For example, there is no need to change conditions under which ion implantation is performed for forming the channel region, the LDD regions 10 and 11, or the source/drain regions 14 and 15. In addition, the low leakage transistor and the high performance transistor having the gate insulating films between which a predetermined difference in thickness exists and which are equal in nitrogen concentration profile are formed in the core section. This improves the performance and reliability of the core section. Therefore, a high performance semiconductor device with high reliability can be fabricated.

With the semiconductor device fabrication method according to the present invention the first SiON film is formed by the first film formation, part of the first SiON film is removed, the second SiON film is formed in the region where the first SiON film is removed by the second film formation, and the third SiON film including the first SiON film is formed in the region where the first SiON film is left. As a result, gate insulating films between which a predetermined minute difference in thickness exists and which have a predetermined nitrogen concentration profile can be formed. Accordingly, in a semiconductor device having an I/O section and a core section, for example, a low leakage transistor and a high performance transistor can accurately be formed in the core section. If this method is used, it is possible to fabricate a high performance semiconductor device with high reliability without changing conditions under which a step other than a gate insulating film formation step is performed.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method for fabricating a semiconductor device having transistors of plural types in which gate insulating films of different thicknesses are used, the method comprising the steps of:
forming a first silicon oxide nitride film over a silicon substrate by performing first film formation on the silicon substrate;
leaving the first silicon oxide nitride film formed over the silicon substrate in a region in which one transistor is to be formed and removing the first silicon oxide nitride film formed over the silicon substrate in a region in which an other transistor is to be formed; and
performing second film formation in the region in which the one transistor is to be formed and in which the first silicon oxide nitride film is left and the region in which the other transistor is to be formed and in which the first silicon oxide nitride film is removed for forming a second silicon oxide nitride film in the region in which the other transistor is to be formed and in which the first silicon oxide nitride film is removed and for forming a third silicon oxide nitride film including the first silicon oxide nitride film in the region in which the one transistor is to be formed and in which the first silicon oxide nitride film is left.

2. The method according to claim 1, wherein in the step of forming the first silicon oxide nitride film over the silicon substrate by performing the first film formation on the silicon substrate, the first silicon oxide nitride film is formed so that a difference in thickness between the second silicon oxide nitride film formed in the region in which the other transistor is to be formed and in which the first silicon oxide nitride film is removed by performing the second film formation later and the third silicon oxide nitride film including the first silicon oxide nitride film formed in the region in which the one transistor is to be formed and in which the first silicon oxide nitride film is left by performing the second film formation later is greater than or equal to 0.03 nm and smaller than or equal to 0.15 nm.

3. The method according to claim 2, wherein the second silicon oxide nitride film and the third silicon oxide nitride film are 2 nm or less in thickness.

4. The method according to claim 1, wherein in the step of forming the first silicon oxide nitride film over the silicon substrate by performing the first film formation on the silicon substrate, the first silicon oxide nitride film is formed so that the second silicon oxide nitride film formed in the region in which the other transistor is to be formed and in which the first silicon oxide nitride film is removed by performing the second film formation later and the third silicon oxide nitride film including the first silicon oxide nitride film formed in the region in which the one transistor is to be formed and in which the first silicon oxide nitride film is left by performing the second film formation later becomes equal in nitrogen concentration profile.

5. The method according to claim 4, wherein a difference in nitrogen concentration between an interface between the second silicon oxide nitride film and the silicon substrate and an interface between the third silicon oxide nitride film and the silicon substrate is smaller than or equal to 0.5%.

6. The method according to claim 1, wherein the one transistor and the other transistor are formed in a core section of the semiconductor device having an I/O section and the core section.

7. The method according to claim 1, wherein:
the third silicon oxide nitride film is a gate insulating film of the one transistor; and
the second silicon oxide nitride film is a gate insulating film of the other transistor.

8. A semiconductor device having transistors of plural types in which gate insulating films of different thicknesses are used, a difference in thickness between a gate insulating film of one transistor and a gate insulating film of an other transistor being greater than or equal to 0.03 nm and smaller than or equal to 0.15 nm, the gate insulating film of the one transistor and the gate insulating film of the other transistor being equal in nitrogen concentration profile.

9. The semiconductor device according to claim 8, wherein a difference in nitrogen concentration between an interface between the gate insulating film of the one transistor and a silicon substrate and an interface between the gate insulating film of the other transistor and the silicon substrate is smaller than or equal to 0.5%.

10. The semiconductor device according to claim 8, wherein:
the semiconductor device has an I/O section and a core section; and
the one transistor and the other transistor are formed in the core section.
